(19) United States
(12) Patent Application Publication
(10) Pub. No.: US 2008/0203459 A1
(43) Pub. Date: Aug. 28, 2008

(54) Method of manufacturing a semiconductor device and semiconductor device

(76) Inventor: Dirk Caspary, Dresden (DE)

Correspondence Address: SLATER & MATSIL, L.L.P., 17950 PRESTON ROAD, SUITE 1000, DALLAS, TX, 75252, US

(21) Appl. No.: 11/711,486

(22) Filed: Feb. 27, 2007

(51) Int. Cl. H01L 27/24; H01L 21/78

(52) U.S. Cl. 257/315; 438/128; 257/E21.599; 257/E27.004

(57) ABSTRACT

A carrier is structured with isolation regions in a precise fashion. First structures and second structures are formed above a carrier. At least one of the second structures is removed selectively with respect to the first structures. At least one recess in the carrier is formed according to the structure thus obtained. An embodiment of a semiconductor device that may be produced in this way is provided with at least one insulating striplike region and/or a plurality of insulating regions that are arranged at distances from one another along a line.

### TECHNICAL FIELD

The present invention generally relates to methods of manufacturing semiconductor devices, especially semiconductor memory devices.

### BACKGROUND

Semiconductor memory devices have a carrier, which usually encompasses a semiconductor substrate. The carrier can especially be a silicon substrate or a structure known as SoO (silicon on oxide) or SOI (silicon on insulator), which is formed of a bulk silicon layer, an insulating layer and a so-called body silicon layer provided for integrated components. At a surface of the carrier, isolating structures are provided, which may especially be shallow trenches. The trenches may be left open or filled with a dielectric, i.e., electrically insulating, material.

Conventional flash memory devices have a memory cell array of individually programmable memory cells. An erasure is performed for groups of memory cells in common, which are referred to as sectors or blocks. The sectors are often separated by isolating structures, especially by trenches in a substrate or semiconductor layer.

The memory cells of a memory array are addressed by bitlines and by wordlines. The wordlines connect gate electrodes of the transistor structures forming the memory cells, and the bitlines connect source/drain regions and may be electrically conductively doped regions in the semiconductor material. If a plurality of sectors is present, they can be separated by insulating regions that are arranged between two neighboring bitlines.

An embodiment of the invention can be applied to different kinds of memory devices, especially to non-volatile memory devices. Non-volatile memory devices can be provided with a charge-trapping memory layer sequence formed of a bottom dielectric layer, a charge-trapping layer and a top dielectric layer, especially an oxide/nitride/oxide layer sequence. Programming is usually performed by injection of charge carriers from a channel (CHE, channel hot electrons) through the bottom dielectric layer. The material of the charge-trapping layer is selected to enable charge carriers to be trapped in locally confined positions within this layer. Instead, for example, a floating gate electrode can be provided as a storage means.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 shows a cross-section of an intermediate product of an embodiment of the method according to the invention after the application of a first material;

FIG. 2 shows a cross-section according to FIG. 1 of a further intermediate product after the formation of a first mask and first line structures;

FIG. 3 shows a cross-section according to FIG. 2 of a further intermediate product after the application of a second material;

FIG. 4 shows a cross-section according to FIG. 3 of a further intermediate product after the formation of a second mask;

FIG. 5 shows a cross-section according to FIG. 4 of a further intermediate product after the application of a conductive material;

FIG. 6 shows a cross-section according to FIG. 5 of a further intermediate product after the planarization of the surface;

FIG. 7 shows a cross-section according to FIG. 6 of a further intermediate product after the formation of second line structures;

FIG. 8 shows a cross-section according to FIG. 7 of a further intermediate product after the implantation of conductor lines;

FIG. 9 shows a cross-section according to FIG. 8 of a further intermediate product after the removal of the second line structures;

FIG. 10 shows a cross-section according to FIG. 9 of a further intermediate product after the formation of wordlines;

FIG. 11 shows a cross-section according to FIG. 6 of an intermediate product of a further embodiment;

FIG. 12 shows a plan view onto a memory cell array;

FIG. 13 is a flow chart of a method according to an embodiment of the invention;

FIG. 14 shows a plan view of an intermediate product of still a further embodiment;

FIG. 15 shows the cross-section indicated in FIG. 14 of a further intermediate product after the formation of isolation fillings;

FIG. 16 shows a plan view of the intermediate product of FIG. 15; and

FIG. 17 shows a plan view according to FIG. 16 of a further intermediate product after the formation of bitline contacts.

### DETAILED DESCRIPTION OF ILLUSTRATIVE EMBODIMENTS

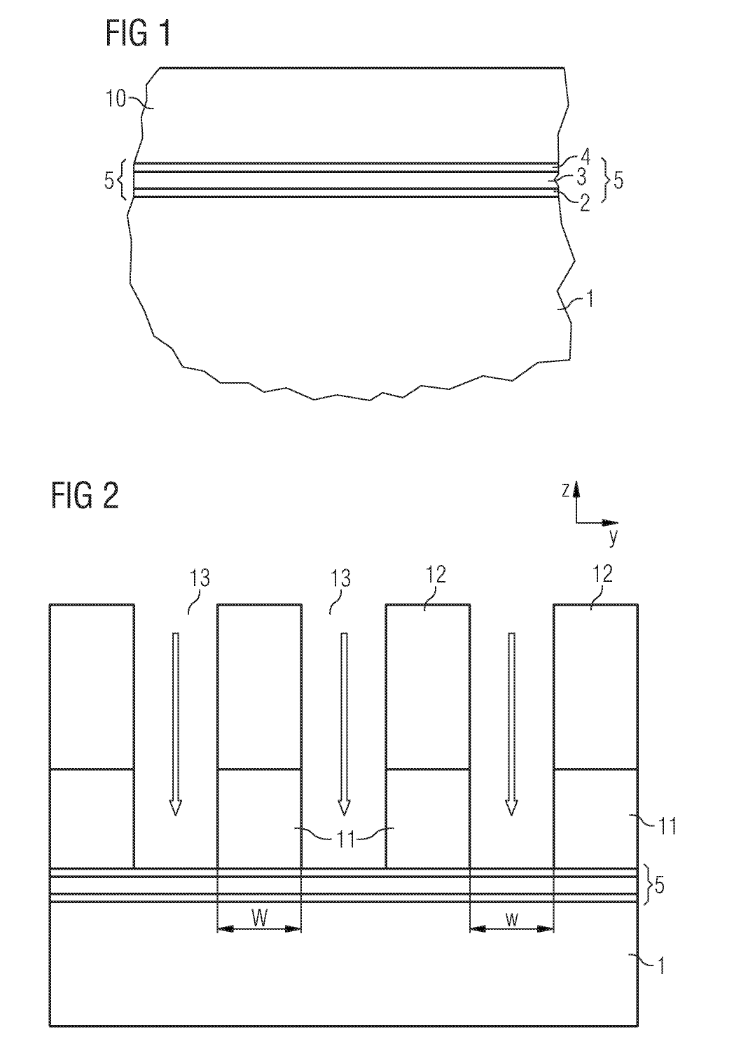

According to an embodiment of the invention, a first intermediate product as shown in the cross-section of FIG. 1 is obtained using a carrier 1, which can be a semiconductor substrate, SoO, SOI or the like or any carrier having a layer of one of these materials. If the device is intended as a semiconductor memory device, a memory layer sequence 5 can be deposited. The memory layer sequence 5 may encompass a bottom dielectric layer 2, which can be an oxide, for example, a charge-trapping layer 3 of a dielectric material that is suitable for charge-trapping, which can be nitride, for example, on the bottom dielectric layer 2, and a top dielectric layer 4, which can be the same material as the bottom dielectric layer 2, on the charge-trapping layer 3. A memory layer sequence 5 is shown in the figures as a part of the described embodiments by way of example, but the memory layer sequence 5 is only optional and can as well be substituted with a floating gate electrode, for example. A layer of a material, hereinafter designated as first material 10, is applied, which can be nitride, for example, especially silicon nitride.

A first mask 12, as shown in FIG. 2, is formed on the layer of the first material 10, which is patterned by means of the first mask 12. The first material 10 is removed in the areas of the openings 13 of the first mask 12, so that a plurality of first structures 11 is formed. In a further specialized embodiment the first structures 11 can be line structures having a longitudinal extension in a first direction perpendicular to the drawing plane (direction x) and running parallel to one another, for example. In this embodiment, every first structure 11 can have the same width W indicated in FIG. 2, and each interspace between two neighboring first structures 11 can have the same width w. A regular pattern of line structures at uniform pitch, possibly corresponding to a minimal dimension that can be structured by a lithography technique, is formed in this embodiment.

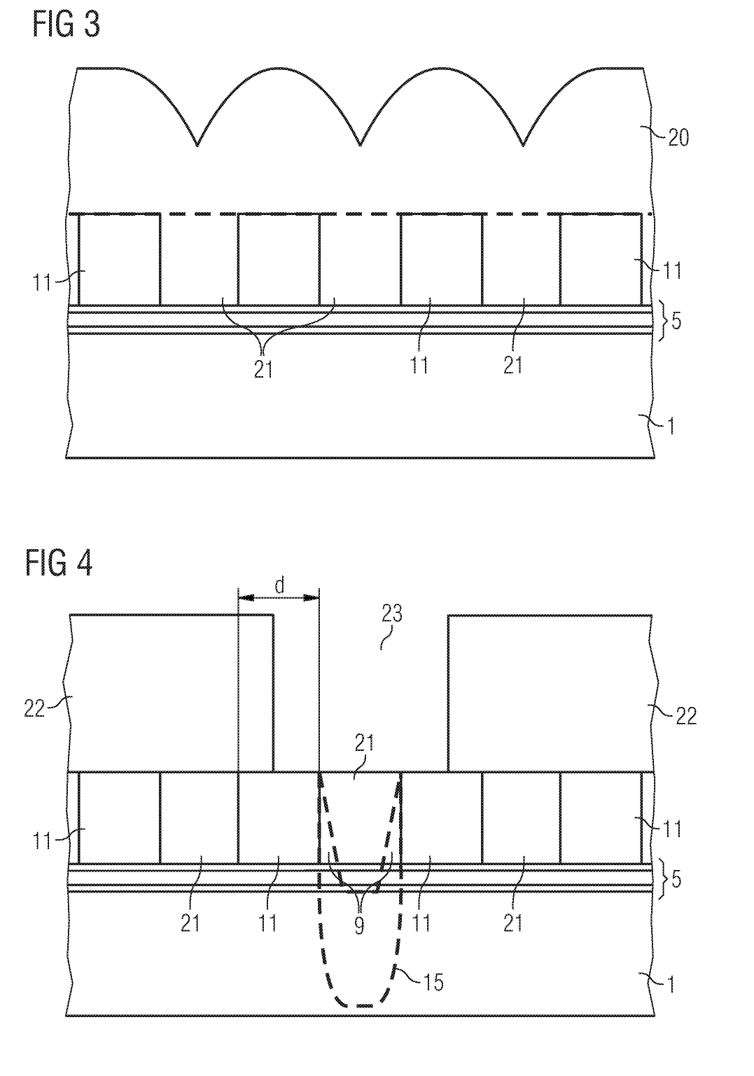

As shown in FIG. 3, a second material 20 that is different from the first material 10 is applied onto and between the first structures 11. The second material 20 can be polysilicon, for example, or any other material that is at least partially selectively etchable with respect to the first material 10. The surface is planarized approximately to the level indicated by the horizontal broken line in FIG. 3, which can be done by CMP (chemical mechanical polishing). The remaining portions of the second material 20 form second structures 21. In the embodiment shown in FIG. 3, the second structures 21 completely fill the gaps between the first structures 11.

As shown in FIG. 4, a second mask 22 having at least one opening 23 is formed on the planarized surface. The second mask 22 covers most of the first structures 11 and second structures 21. In the example of FIG. 4, about half of the top surface of two neighboring first structures 11 that are arranged adjacent to a second structure 21 that is exposed by the opening 23 is left free from the second mask 22. Even in the case of misalignments due to the lithography that is applied when the openings 23 are produced, the width of the first structures 11 is sufficient to guarantee that all the second structures 21 that are not to be exposed remain completely covered by the second mask 22. The second structures 21 that are not covered by the second mask 22 are removed, preferably by an etching step, selectively to the first material, so that the first structures 11 are maintained. The memory layer sequence 5, if it is provided, can be removed in the area of the removed second structures 21 as well. As indicated with the upper broken lines in FIG. 4, spacers 9 may be formed after the removal of the second structures 21 at sidewalls of the previously contiguous first structures 11. In the area of the removed second structures 21, between the spacers 9, if they are provided, trenches 15 are etched at least partially into the carrier 1. The form of the sidewalls and bottom of a trench 15 is indicated in FIG. 4 with the lower broken line.

As shown in FIG. 5, a dielectric material 7 can then be applied to fill the trenches 15. A dielectric liner, not shown in FIG. 5, may be applied on the inner sidewalls and the bottom of the trenches in order to improve the electrical insulation, before the dielectric material 7 is applied. The dielectric material 7 filling the trenches can be, e.g., silicon oxide or another appropriate dielectric material. The surface is planarized, to a level as, e.g., indicated by the horizontal broken line in FIG. 5, and dielectric material 7 is removed except for the remaining trench isolation 16, which can be used to separate two sectors or blocks of a memory cell array from one another.

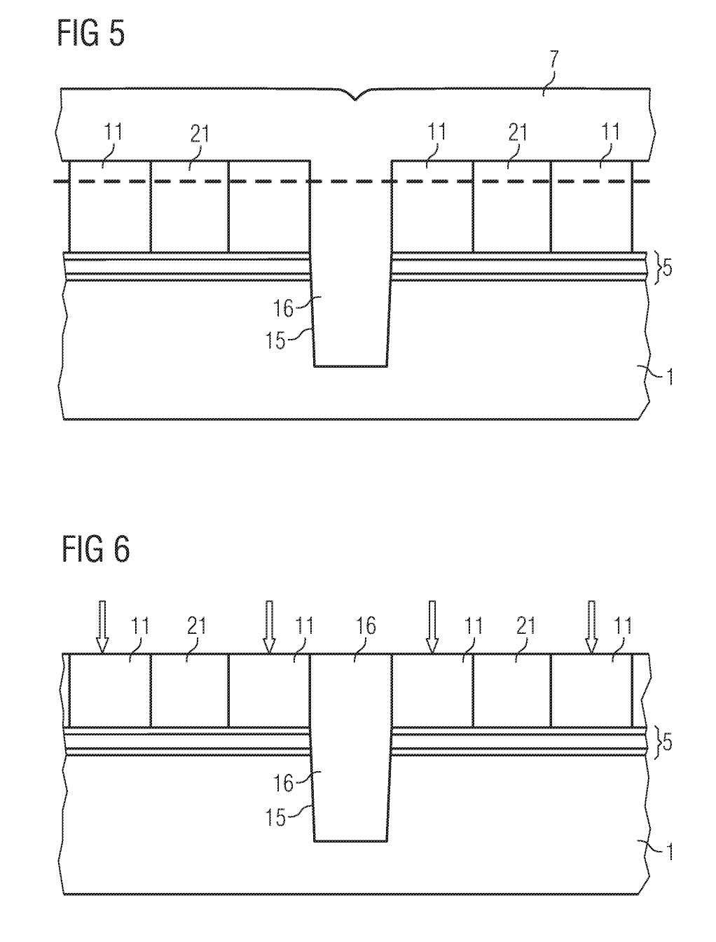

FIG. 6 shows a cross-section of the intermediate product that is obtained by the planarization. In the alternate arrangement of first structures 11 and second structures 21 individual second structures 21 have been replaced by a trench isolation 16. For the sake of simplicity, the figures show only one trench isolation 16, but a plurality of trench isolations 16 can be provided as well. The first structures 11 can then be removed selectively to the second structures 21 and to the trench isolations 16, as indicated by the arrows in FIG. 6.

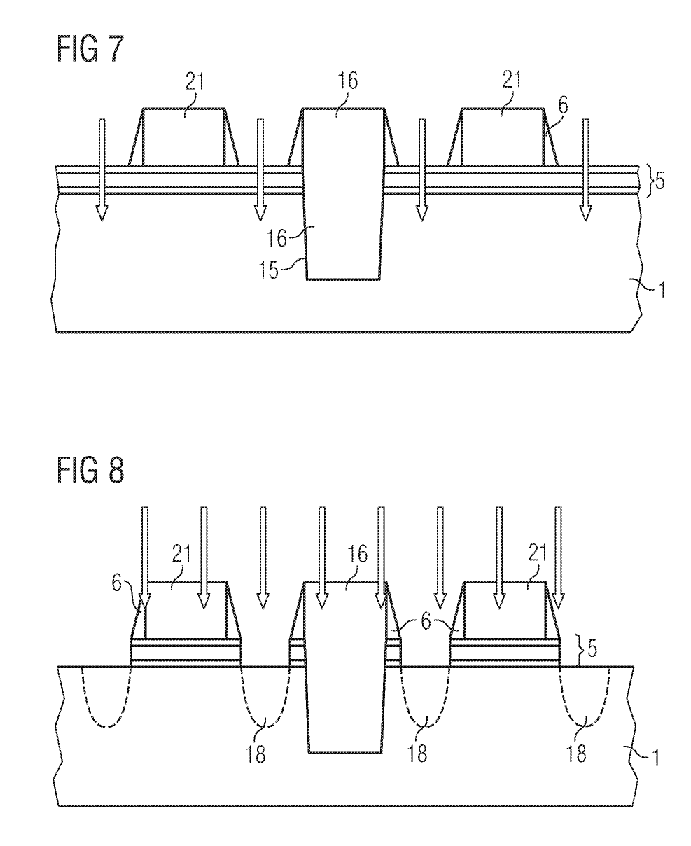

FIG. 7 shows a cross-section of the further intermediate product that is obtained after the removal of the first structures 11. Spacers 6 can optionally be applied to the sidewalls of the second structures 21 in the interspaces that had previously been occupied by the first structures. An implantation of a dopant, indicated by the arrows in FIG. 7, is performed into the semiconductor material to produce doped regions, which may serve as buried conductor lines, especially as buried bitlines, for example. During the implantation the trench isolations 16 the second structures 21 are used as a mask. Further applications of spacers and further implantations can take place according to the special requirements of the devices that are to be produced. The memory layer sequence 5, if it is provided, can be patterned before or after the implantation. In the example shown in FIG. 7, the memory layer sequence 5 is still present between the second structures 21 during the implantation.

FIG. 8 shows a further intermediate product that is obtained after the formation of the doped regions, which are buried conductor lines 18 in the described embodiment, and, in this example, after a subsequent removal of the memory layer sequence 5 in the areas between the second structures 21. The second structures 21 are then at least partially removed together with upper portions of the trench isolations 16. This can be achieved by an etching step or a further planarization, indicated by arrows in FIG. 8.

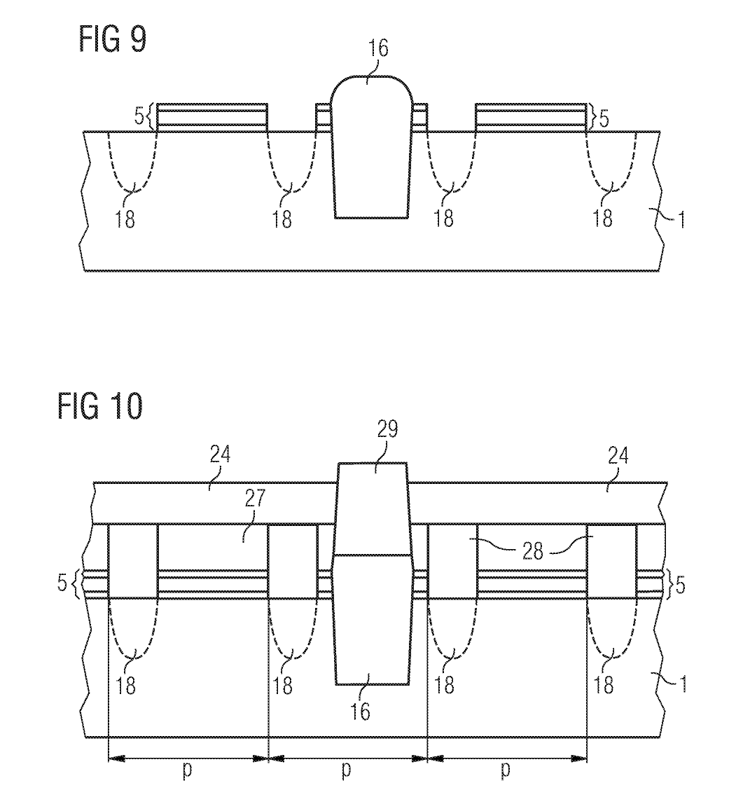

FIG. 9 shows a cross-section according to FIG. 8, after the second structures have at least partially been removed. It also shows that the conductor lines 18 can be arranged in a pattern of congruent surface areas that might be arranged at a uniform distance from one another in spite of the presence of the trench isolations 16. Thus a minimal pitch of the conductor lines 18 is not disturbed by an intermediate isolation region that is formed by a trench isolation 16. Especially in the case of a memory cell array that is subdivided into sectors or blocks, a periodic sequence of bitlines need not be interrupted by the isolations between adjacent sectors, but can be uniform throughout the area of the memory cell array, even when passing the boundaries between the sectors.

FIG. 10 shows a cross-section according to the previous figures of an embodiment of a memory product that can be produced by optional further method steps. Electrically conductive structures 27, which are intended as gate electrodes of transistor structures and can be electrically conductively doped polysilicon, for example, are arranged on remaining portions of the memory layer sequence 5. If the second structures 21 are formed of electrically conductive material like doped polysilicon, for example, they need not be removed completely, so that the conductive structures 27 can be residual sections of the second structures 21, which form gate electrode stacks, for example. Insulating structures 28 can be formed on the conductor lines 18. Wordlines 24 are arranged above, which connect rows of conductive structures 27. The longitudinal extension of the wordlines 24 might be arranged transverse to the longitudinal extension of the buried conductor lines 18, which are provided as bitlines in this embodiment. If the trench isolations 16 are filled with dielectric material, they can be covered with further isolating structures 29.

The pitch p of the arrangement of conductor lines 18 is indicated at the bottom of FIG. 10. It is the same between neighboring conductor lines 18 that are not separated by a trench isolation 16 as between the two conductor lines 18 that are present on both sides of the trench isolation 16 in its immediate vicinity. By the described method it is therefore possible to maintain the bitline pitch of a memory device even across the boundary of two adjacent sectors. It enables a self-aligned implantation of the conductor lines 18 without a disturbance of the uniform pattern. The range of permissible manufacturing tolerances is increased, since the width of the masking structures allows some lateral misalignment that is due to the applied lithography. Thus the density of the bitlines and the density of the memory cells of a memory device can be increased.

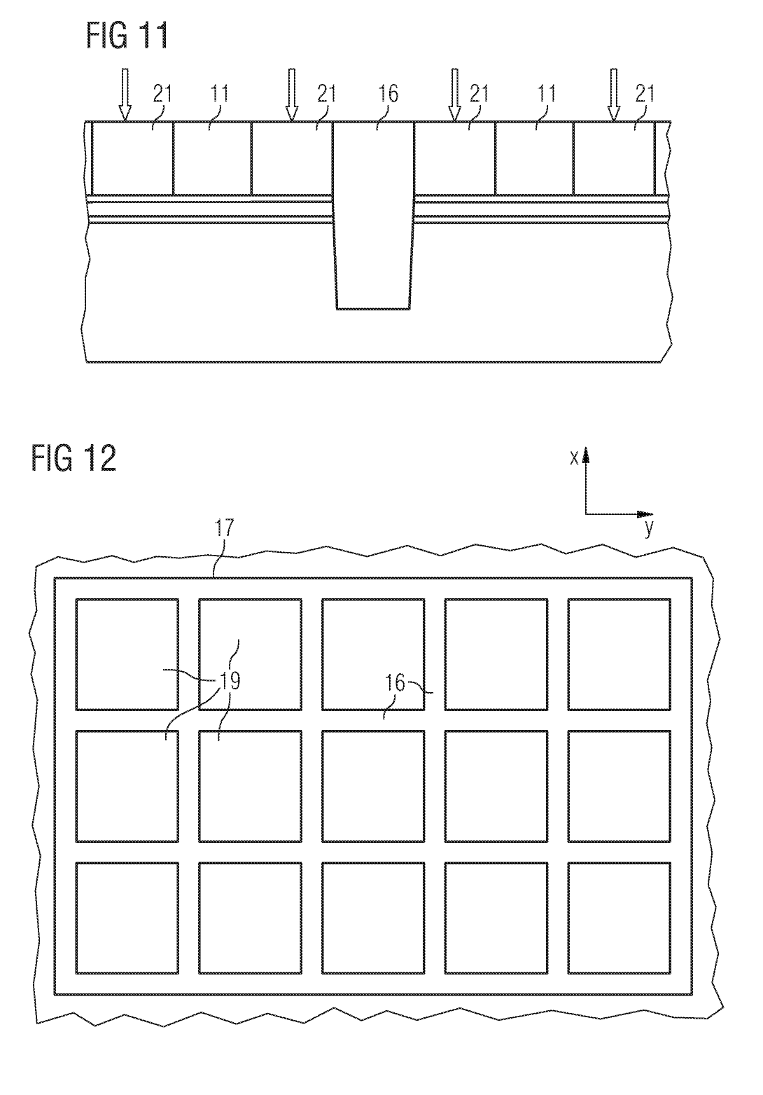

FIG. 11 shows a cross-section according to FIG. 6 of a further embodiment, in which the roles of the first structures 11 and the second structures 21 are interchanged. After the formation of the first structures 11 and the second structures 21, individual first structures 11 are removed to form trench isolations 16 in their place. Then the second structures 21 are removed, as indicated by the arrows in FIG. 11. Further method steps can follow according to the ones that have already been described, but using the first structures 11 as a mask.

FIG. 12 is a schematic plan view of a memory cell array 17 having a plurality of sectors 19, each of which occupies a rectangular area in this embodiment and consists of a plurality of memory cells. The memory cells are connected to parallel wordlines and parallel bitlines, each of which pass several sectors 19, the wordlines usually being arranged transverse to the bitlines. The sectors 19 are separated from one another by trench isolations 16. Such a device can be produced by one of the described methods.

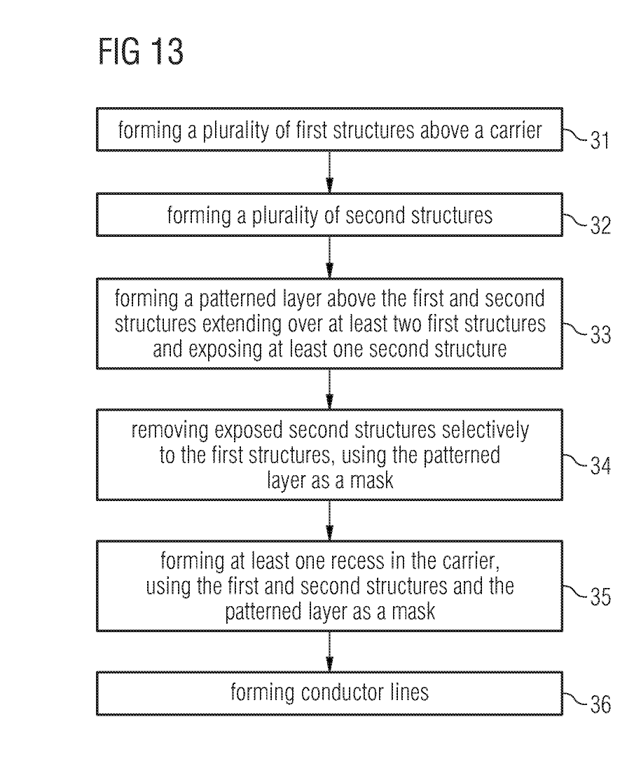

FIG. 13 is a flow chart of the main method steps of the first embodiment as described above. A plurality of first structures is formed above a carrier, step 31. A plurality of second structures is formed, step 32. A patterned layer is formed above the first and second structures extending over at least two first structures and exposing at least one second structure, step 33. Exposed second structures are removed selectively to the first structures, using the patterned layer as a mask, step 34. At least one recess is formed in the carrier, using the first and second structures and the patterned layer as a mask, step 35. Conductor lines are formed, step 36.

In an embodiment of the invention at least one recess is arranged in such a fashion that it laterally insulates an area of the carrier that is provided for a bitline contact. In other embodiments of this type, a plurality of recesses is formed, which are arranged at a distance from one another along a line, possibly in periodic succession, for example. The recesses insulate areas of the conductor lines laterally on two opposite sides, these areas being provided for bitline contacts. The embodiment can additionally have trench isolations as described above. In this case the plurality of recesses insulating the bitline contacts can be arranged along a direction that is normal to the longitudinal extension of the trench isolations. The arrangement might be continuous and it might be interrupted.

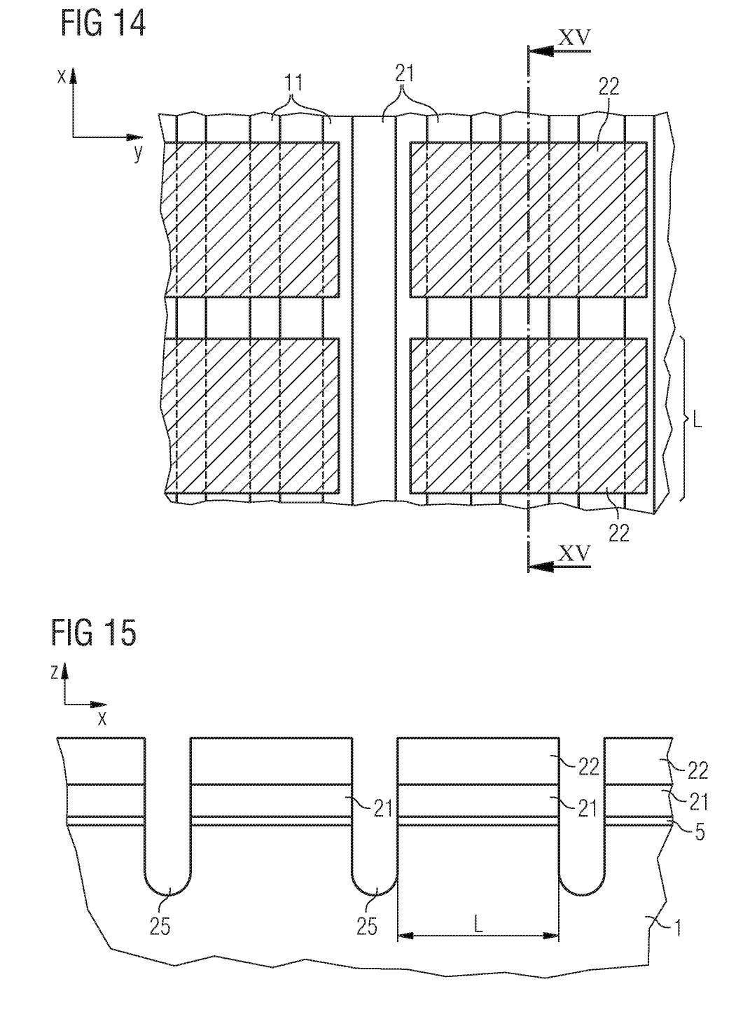

FIG. 14 is a plan view of an intermediate product according to this embodiment. First structures 11 and second structures 21 are alternatingly arranged in striplike fashion above a carrier, especially on a memory layer sequence 5. The second mask 22, which is used to remove a portion of the first structures 21, is structured in such a manner that the opening of the second mask 22 forms a cross or a grid. Thus at least one second structure 21 that forms a strip extending in direction x, which is vertical in the drawing of FIG. 14, is completely exposed at least within the area of the memory cell array. Transversely to this, in direction y, the second mask 22 has at least one striplike opening, which alternatively exposes portions of the first structures 11 and the second structures 21. When the portions of the second structures 21 that are not covered by the second mask 22 are removed, at least a trench in direction x and a plurality of recesses of rectangular shape along direction y are formed.

The described example includes several alterations and substitutions by which the embodiment can be varied. Although it can be advantageous to have both a trench isolation and a plurality of short recesses, the trench isolation is not necessary if only an insulation of the bitline contacts is desired. In this case the second mask 22 is structured differently, having only at least one striplike opening that extends in direction y, for instance.

FIG. 15 is a cross-section at the position that is indicated in FIG. 14. The cross-section shows a further intermediate product after the formation of trenches and/or recesses, which can be effected by an etching step using the second mask 22. First the portions of the second structures 21 that are not covered by the second mask 22 are selectively removed with respect to the first structures 11, and then the recesses 25 are etched selectively to the first structures 11 and preferably also selectively to the remaining portions of the second structures 21 below the second mask 22, in order to avoid an underetch. In the embodiment shown in FIGS. 14 and 15, there are several parallel striplike openings of the second mask 22 along direction y, and a plurality of recesses 25 is formed at the locations where lines in directions x and y of a gridlike pattern cross. After the recesses 25 have been formed, they can be filled with a dielectric material. The distance between the recesses 25 in direction x corresponds to the length L of the sections of the second mask 22, measured in direction x (FIG. 14).

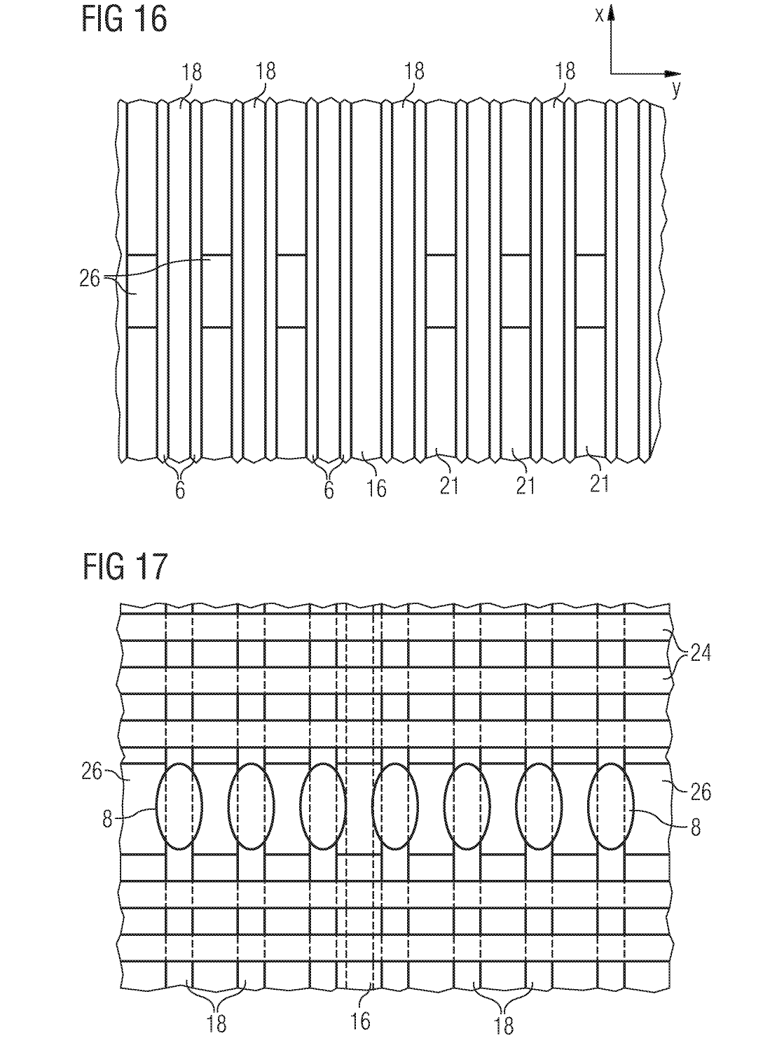

FIG. 16 is a plan view of a further intermediate product, which is obtained by the introduction of a dielectric material into the trenches 15 and recesses 25 to form trench isolations 16 and recess isolations 26, a subsequent planarization, and the removal of the first structures 11. Spacers 6 can be applied to the sidewalls of the remaining sections of the second structures 21 and the upper portions of the dielectric material that forms the trench isolations 16 and the recess isolations 26, similarly to the structure that is shown in FIGS. 7 and 8. In the areas between the spacers, the conductor lines 18 are formed by an implantation of a dopant. The recess isolations 26 improve an electric insulation between the areas that are provided for bitline contacts on the conductor lines 18. The optional trench isolations 16 may be provided to separate sectors of a memory cell array.

FIG. 17 shows a plan view according to FIG. 16 for a further intermediate product after the application of bitline contacts 8 of oval shape and wordlines 24 running transversely to the conductor lines 18. The bitline contacts 8 are disposed in a central position between two opposite recess isolations 26. Because of the precisely rectangular shape of the recess isolations 26, which can be achieved by the described method, the electric insulation between neighboring bitline contacts 8 is improved. Thus the recess isolations 26 can be kept short as compared to conventional isolations, which have rounded corners near the buried conductor lines and must extend correspondingly further in direction x to secure a sufficient electric insulation.

Although the present invention and its advantages have been described in detail, it should be understood that various changes, substitutions and alterations can be made herein without departing from the spirit and scope of the invention as defined by the appended claims.

What is claimed is:

1. A method of manufacturing a semiconductor device, the method comprising:
forming a plurality of first structures in a layer above a carrier, the first structures being arranged in a periodic succession;
forming a plurality of second structures in the layer, the second structures being arranged in a periodic succession alternating with the first structures;
forming a patterned layer above the first and second structures, the patterned layer extending over at least two of the first structures and exposing at least one of the second structures;
removing the at least one exposed second structure; and
forming at least one recess in the carrier, using the structures and the patterned layer as a mask.

2. A method of manufacturing a semiconductor device, the method comprising:
forming a plurality of first structures in a layer above a carrier, the first structures being arranged in a periodic succession;
forming a plurality of second structures in the layer, the second structures being arranged in a periodic succession alternating with the first structures;
forming a patterned layer above the first and second structures, the patterned layer extending over at least two of the first structures and exposing at least one of the second structures;
removing the at least one exposed second structure;
forming at least one recess in the carrier, using the structures and the patterned layer as a mask;
removing the patterned layer and the first structures; and
performing an implantation of a dopant using remaining ones of the second structures as a mask.

3. The method of claim 1, further comprising:
forming an insulation layer on the carrier before forming the pluralities of first and second structures.

4. The method of claim 1, further comprising:
filling the at least one recess with a dielectric material.

5. The method of claim 1, wherein the second structures form gate electrode stacks.

6. The method of claim 1, wherein the at least one recess is arranged to separate sectors of a memory cell array.

7. The method of claim 1, wherein the at least one recess is arranged to separate areas of the carrier that are provided for bitline contacts.

8. The method of claim 7, further comprising:
forming a plurality of recesses in the carrier together with the at least one recess, the recesses being arranged in periodic succession to separate areas of the carrier that are provided for bitline contacts.

9. A method of manufacturing a semiconductor device, comprising:
forming a periodically structured layer from a first material and a second material above a carrier of a third material, the second material and the third material being selectively removable with respect to the first material;
forming a patterned layer above the structured layer, the patterned layer covering at least two portions of the first material and exposing at least one portion of the second material;
removing the exposed portion of the second material selectively with respect to the first material; and
forming at least one recess in the third material selectively with respect to the first material, using the structured layer and the patterned layer as a mask.

10. The method of claim 9, wherein the first material is selectively removable with respect to the second material and the third material, the method further comprising:
filling the at least one recess with a dielectric material;
removing the pattered layer and the first material selectively with respect to the second material and the third material; and
performing an implantation to form diffusion lines, using remaining portions of the second material as a mask.

11. The method of claim 10, wherein a shallow trench isolation between sectors of a memory cell array is formed by filling the at least one recess.

12. The method of claim 10, wherein a bitline contact isolation is formed by filling the at least one recess.

13. The method of claim 9, wherein the first and second materials are alternatingly arranged in strips that are parallel to one another.

14. The method of claim 9, further comprising:
forming a memory layer sequence comprising a bottom dielectric layer, a charge-trapping layer and a top dielectric layer on the carrier before forming the periodically structured layer.

15. The method of claim 14, further comprising:
forming gate electrode structures on the memory layer sequence.

16. A semiconductor device comprising:
a memory cell array arranged in an area of a carrier;
a plurality of diffused conductor lines arranged in periodic succession in the area;
bitline contacts applied on the conductor lines; and
recess isolations formed in the carrier between pairs of conductor lines adjacent to the bitline contacts.

17. The semiconductor device of claim 16, further comprising:
gate electrode stacks arranged above areas between the conductor lines; and
trench isolations arranged in the carrier immediately adjacent to the gate electrode stacks.

18. A semiconductor device comprising:
a carrier having a surface and recess isolations;
every recess isolation occupying a rectangular area of the surface; and
the recess isolations being arranged at a distance from one another along at least one line.

19. The semiconductor device of claim 18, wherein the recess isolations are arranged along lines of a plurality of parallel straight lines.

20. The semiconductor device of claim 18, further comprising:
trench isolations having a longitudinal extension transversely to the lines along which the recess isolations are arranged.
